(19) United States
(12) Patent Application Publication
(10) Pub. No.: US 2012/0229183 A1
(43) Pub. Date: Sep. 13, 2012

(54) POWER-ON RESET CIRCUIT AND ELECTRONIC DEVICE HAVING THE SAME

(76) Inventor: Seungwon Lee, Yongin-si (KR)

(21) Appl. No.: 13/414,911

(22) Filed: Mar. 8, 2012

(30) Foreign Application Priority Data
Mar. 9, 2011 (KR) 10-2011-0020974

(51) Int. Cl. H03L 7/00

(52) U.S. Cl. 327/143

(57) ABSTRACT

A power-on reset circuit includes a current source circuit supplying a current that varies according to a temperature to a first node, a first transistor connected between the first node and a ground voltage and having a gate connected with a power supply voltage, and an output circuit connected with the first node and outputting a power-on reset signal in response to a signal applied to the first node.

### CROSS-REFERENCE TO RELATED APPLICATIONS

This application claims priority under 35 U.S.C §119 to Korean Patent Application No. 10-2011-0020974, filed on Mar. 9, 2011, the disclosure of which is incorporated by reference in its entirety herein.

### BACKGROUND

1. Technical Field

Exemplary embodiments of the inventive concept relate to a power-on reset circuit and a smart card including the power-on reset circuit.

2. Discussion of Related Art

An electronic device may include a power-on reset circuit. The power-on reset circuit may be used to activate elements within the electronic device after a provided external power supply is stabile. An increasing number of electronic devices are being generated that operate at a low power supply voltages. However, a power-on reset circuit that receives a low power supply voltage may be adversely affected when temperatures are lower or higher than the optimal operating temperature.

Thus, there is a need for a power-on reset circuit that is more resistant to temperature fluctuations.

### SUMMARY

According to an exemplary embodiment of the inventive concept, a power-on reset circuit includes a current source circuit, a first transistor, and an output circuit. The current source circuit supplies a current that varies according to change in temperature to a first node. The first transistor is connected between the first node and a ground voltage and has a gate connected with a power supply voltage. The output circuit is connected with the first node and outputs a power-on reset signal in response to a signal applied to the first node.

The current source circuit may include a second transistor, a reference voltage generator, and a bias control circuit. The second transistor may be connected between the power supply voltage and the first node and have a gate connected to receive a bias control signal. The reference voltage generator may output the bias control signal. The reference voltage generator may include a third transistor connected between the power supply voltage and a reference voltage node and have a gate connected to receive the bias control signal. The bias control circuit may output the bias control signal to enable output of a stable reference voltage to the reference voltage node.

The bias control circuit may include a first resistor connected between the reference voltage node and a second node, a first diode connected between the second node and a ground voltage, a second resistor connected between the reference voltage node and a third node, a third resistor connected between the third node and a fourth node, a second diode connected between the fourth node and the ground voltage, and an operational amplifier having a first input terminal connected with the second node, a second input terminal connected with the third node, and an output terminal outputting the bias control signal.

The first diode may include a plurality of diodes connected in parallel with one another between the second node and the ground voltage.

The output circuit may include an inverter which inverts a signal applied to the first node and outputs the inverted signal as the power-on reset signal.

The current source circuit may be configured to increase the current supplied to the first node when the temperature increases, and the current source circuit may be configured to decrease the current supplied to the first node when the temperature decreases.

An electronic device according to an exemplary embodiment of the inventive concept may include a bandgap reference outputting a bias control signal depending on a peripheral temperature, a power-on reset circuit outputting a power-on reset signal when a power supply voltage increases to a predetermined level, and an internal circuit operating in response to the power-on reset signal. The power-on reset circuit may include a first transistor connected between the power supply voltage and a first node and having a gate connected to receive the bias control signal, a second transistor connected between the first node and a ground voltage and having a gate connected with the power supply voltage, and an inverter outputting the power-on reset signal in response to a signal applied to the first node.

The band gap reference may include a third transistor connected between the power supply voltage and a reference voltage node and having a gate connected to receive the bias control signal, a first resistor connected between the reference voltage node and a second node, a first diode connected between the second node and the ground voltage, a second resistor connected between the reference voltage node and a third node, a third resistor connected between the third node and a fourth node, a second diode connected between the fourth node and the ground voltage, and an operational amplifier having a first input terminal connected with the second node, a second input terminal connected with the third node, and an output terminal outputting the bias control signal.

The electronic device may further include a first terminal receiving the power supply voltage and a second terminal receiving the ground voltage.

A voltage of the bias control signal may be varied in proportion to a peripheral temperature.

The electronic device may be a smart card as an example.

The first diode may include a plurality of transistors connected in parallel with one another between the second node and the ground voltage.

According to an exemplary embodiment of the inventive concept, a power-on reset circuit includes a first transistor, an output circuit, and a current source circuit. The first transistor is connected between a first node and a ground voltage and has a gate connected with a power supply voltage. The output circuit is connected to the first node and outputs a power-on reset signal based on a signal applied to the first node. The current source circuit is configured to supply a first current to the first node when a threshold voltage of the first transistor is a value, supply a second current to the first node when the threshold voltage is lower than the value, and supply a third current to the first node when the threshold voltage is higher than the value. The first current is lower than the second current and higher than the third current.

The current source circuit may supply the first current when a current temperature is within a normal temperature operating range for the first transistor, supply the second current when the current temperature is above the range, and supply the third current when the current temperature is below the range.

The output circuit may be an inverter. The current source circuit may include a second transistor that is connected between the power supply voltage and the first node. The current source circuit may vary a control signal in proportion to a peripheral temperature and apply the control signal to a gate of the second transistor.

The current source circuit may further include a third transistor and an operational amplifier. The third transistor is connected between the power supply voltage and a reference voltage node and has a gate connected to receive the control signal. The operational amplifier may have a first input terminal connected to a second node, a second input terminal connected to a third node, and output terminal outputting the control signal.

The current source circuit may further include a first resistor connected between the reference voltage node and the second node and a second resistor connected between the reference voltage node and the third node. The current source circuit may further include a first diode connected between the second node and a ground voltage and a second diode connected between the third node and the ground voltage.

### BRIEF DESCRIPTION OF THE FIGURES

Embodiments of the inventive concept will become apparent from the following description with reference to the following figures.

FIG. 1 is a circuit diagram of a power-on reset circuit according to an exemplary embodiment of the inventive concept.

FIG. 2 is a diagram showing variations of a current flowing through a transistor of the circuit and a power-on reset signal output by the circuit based on temperature changes.

FIG. 3 is a diagram showing variations of a current flowing through a transistor of the circuit and a reference current of the circuit based on temperature changes.

FIG. 4 is an example of a current source circuit of FIG. 1 according to an exemplary embodiment of the inventive concept.

FIG. 5 is a block diagram of an electronic device according to an exemplary embodiment of the inventive concept.

### DETAILED DESCRIPTION

The inventive concept is described more fully hereinafter with reference to the accompanying drawings, in which embodiments of the inventive concept are shown. This inventive concept may, however, be embodied in many different forms and should not be construed as limited to the embodiments set forth herein.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present.

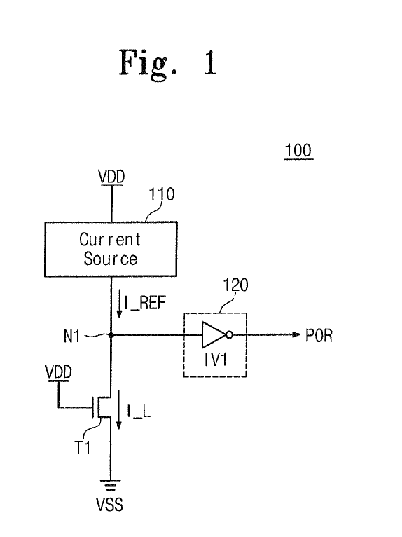

FIG. 1 is a circuit diagram of a power-on reset circuit according to an exemplary embodiment of the inventive concept.

Referring to FIG. 1, a power-on reset circuit 100 may include a current source circuit 110, an output circuit 120, and a first transistor T1. The current source circuit 110 is connected between a power supply voltage VDD and a first node N1, and is configured to supply a reference current I_REF to the first node N1. The power supply voltage VDD may be externally supplied to the power-on reset circuit 100. The first transistor T1 has a gate connected to receive a power supply voltage VDD and is connected between the first node N1 and a ground voltage VSS. For example, the first transistor T1 may be an NMOS transistor. The output circuit 120 is connected to the first node N1 and is configured to output a power-on reset signal POR in response to a signal applied to the first node N1. The output circuit 120 may be an inverter IV1, for example. The inverter IV1 inverts the signal applied to the first node N1 to output it as the power-on reset signal POR.

The level of the power supply voltage VDD may increase gradually at power-up or transition directly to a power-on state from a power-off state. When the level of the power supply voltage VDD is greater than a threshold voltage of the first transistor T1, the first transistor T1 is turned on. When a current to the first node N1 is discharged through the turned-on first transistor T1, the inverter IV1 may output the power-on reset signal POR having a high level.

A threshold voltage of the first transistor T1 may vary according to a peripheral temperature. For example, a threshold voltage of the first transistor T1 may decrease when a peripheral temperature increases above a threshold temperature (e.g., room temperature, a normal operating temperature of the transistor, etc.). Accordingly, the power-on reset signal POR may be set (e.g., activated) to a high level before a power supply voltage VDD increases to a sufficient level. A threshold voltage of the first transistor T1 may increase when a peripheral temperature decreases below the threshold temperature. In this example, although a power supply voltage VDD increases to a sufficient level, it takes longer to reach that level as compared to when a normal operating temperature is present. Thus, a delay time may be experienced before the power-on reset signal POR is set to the high level.

For example, since a small amount of current (e.g., several μA) flows through the first transistor T1 during a rising period of the power supply voltage VDD from 0V to a predetermined voltage level, the amount of current flowing through the first transistor T1 may vary linearly as a peripheral temperature changes. Therefore, the time at which the power-on reset signal POR reaches the high level (e.g., “active time) may vary according to a peripheral temperature.

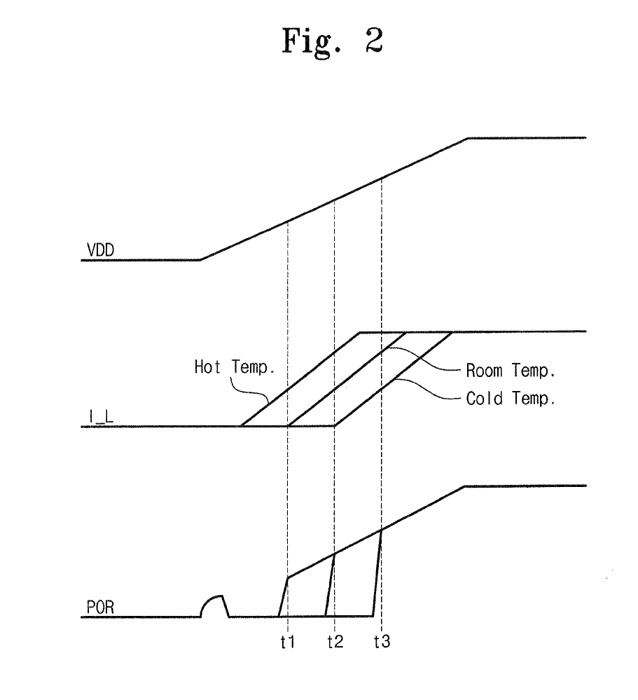

FIG. 2 is a diagram that shows variations of a current flowing through the first transistor of the circuit of 100 of FIG. 1 and a power-on reset signal output by the circuit 100 according to changes in a peripheral temperature.

Referring to FIG. 2, a first transistor T1 may be turned on relatively rapidly at a temperature higher than a room temperature (hereinafter, referred to as a “hot temperature”). The hot temperature enables the amount of current flowing through the first transistor T1 to increase before a power supply voltage VDD increases to a sufficient level. Accordingly, an active time t1 of a power-on reset signal POR occurs earlier as compared with that at the room temperature, which occurs at active time t2. The first transistor T1 may be turned on relatively slowly at a temperature lower than the room temperature (hereinafter, referred to as a “cold temperature”). Due to the cold temperature, although the power supply voltage VDD increases to a sufficient level, a current IL flowing through the first transistor T1 may start to increase at a relatively late active time t3. Accordingly, the active time t3 of a power-on reset signal POR at the cold temperature is later as compared with the room temperature active time t2. Therefore, an active time of the power-on reset signal POR may occur earlier in proportion to an increase in a peripheral temperature, and may occur later in proportion to a decrease in the peripheral temperature (e.g., t1<t2<t3).

Returning to FIG. 1, the current source circuit 110 may generate a reference current I_REF to compensate for a variation of a current I_L flowing through the first transistor T1 according to a variation of the peripheral temperature.

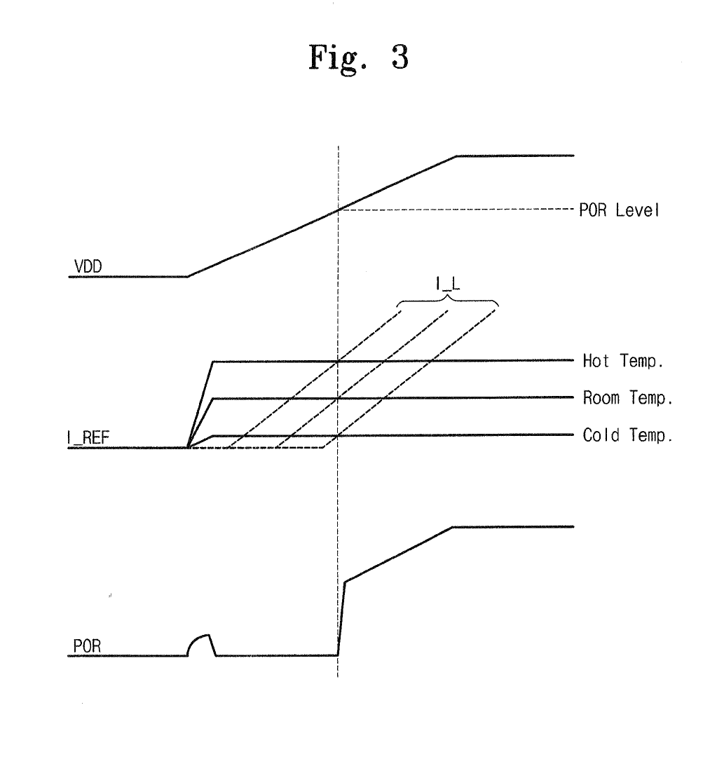

FIG. 3 is a diagram that shows variations of a current flowing through a first transistor of the circuit 100 and a reference current output by the current source 110 according to changes of a peripheral temperature.

Referring to FIGS. 1 and 3, the amount of a reference current I_REF may increase to a first level when a time at which a current I_L flowing through a first transistor T1 occurs at an earlier time due to an increase in a peripheral temperature. When the peripheral temperature is at a room temperature, the reference current I_REF may have a second level. The amount of the reference current I_REF may decrease to a third level when a time at which a current I_L flowing through a first transistor T1 occurs at a later time due to a decrease in the peripheral temperature. As shown in FIG. 3, the first level (see e.g., Hot Temp.) is higher than the second level (see e.g., Room Temp.) and the second level is higher than the third level (see e.g., Cold Temp.). Therefore, a power-on reset signal POR output through an inverter IV1 may transition to a high level within substantially the same amount of time when a power supply voltage VDD increases to a predetermined level, regardless of the peripheral temperature.

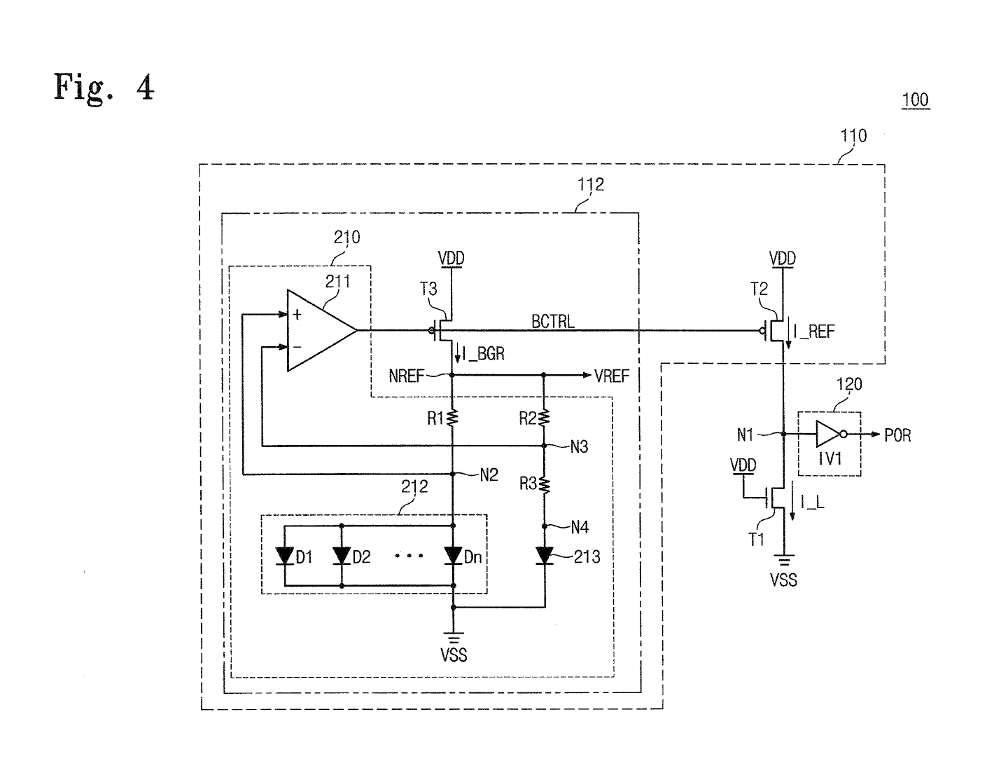

FIG. 4 is an example of a circuit diagram of a current source circuit 110 of the power-on reset circuit 100 of FIG. 1 according to an exemplary embodiment of the inventive concept.

Referring to FIG. 4, a current source circuit 110 may include a bandgap reference 112 and a second transistor T2. The second transistor T2 is connected between a power supply voltage VDD and a first node N1, and has a gate connected to receive a bias control signal BCTRL. The bandgap reference 112 may be configured to generate the bias control signal BCTRL.

The bandgap reference 112 may include a third transistor T3 and a bias control circuit 210. The third transistor T3 is connected between the power supply voltage VDD and a reference voltage node NREF, and has a gate connected to receive the bias control signal BCTRL. The bias control circuit 210 may include an operational amplifier 211, first to third resistors R1, R2 and R3, an array 212 of first diodes (hereinafter, referred to as a diode array), and a second diode 213.

The first resistor R1 is connected between a reference node NREF and a second node N2. The second resistor R2 is connected between the reference node NREF and a third node N3. The third resistor R3 is connected between the third node N3 and a fourth node N4. The diode array 212 is connected between the second node N2 and a ground voltage VSS. The diode array 212 may include a plurality of first diodes which are connected in parallel between the second node N2 and the ground voltage VSS. The second diode 213 is connected between the fourth node N4 and the ground voltage VSS. The operational amplifier 211 has a first input terminal (+) connected with the second node N2 and a second input terminal (−) connected with the third node N3. A voltage of the reference voltage node NREF may become a reference voltage VREF.

When a peripheral temperature increases, the amount of current flowing through each of the diode array 212 and the second diode 213 may increase. The bias control circuit 210 generates the bias control signal BCTRL so that a current I_BGR flowing through the third transistor T3 increases. In this example, the bandgap reference voltage VREF may be generated constantly.

The amount of the current I_BGR flowing to the third transistor T3 may be determined according to the amount of currents flowing through the second and third nodes N2 and N3. For example, the amount of the current I_BGR flowing through the third transistor T3 may be expressed by the following Equation 1.

I_{—}BGR=ln(n)/r1*K/q* T [Equation 1]

In Equation 1, “n” may indicate the number of the first diodes D1 to Dn in the diode array 212, “r1” may indicate a resistance value of the first resistor R1, “K/q” may indicate a constant, and “T” may indicate a peripheral temperature.

As shown by Equation 1, when the peripheral temperature T increases, the current I_BGR flowing through the third transistor T3 increases in amount. Accordingly, since a gate of the third transistor T3 is controlled by the bias control signal BCTRL, a reference current I_REF flowing through the second transistor T2 may increase.

If the amount of current I_L flowing through the first transistor T1 increases due to an increase in a peripheral temperature, the reference current I_REF supplied to the node N1 through the second transistor T2 increases in amount. If the amount of current I_L flowing through the first transistor T1 decreases due to a decrease in the peripheral temperature, the reference current I_REF supplied to the node N1 through the second transistor T2 decreases in amount. Therefore, the power-on reset circuit 100 may cause the power-on reset signal POR to reach a high level within substantially the same amount of time when the power supply voltage VDD increases to a predetermined level, regardless of the peripheral temperature.

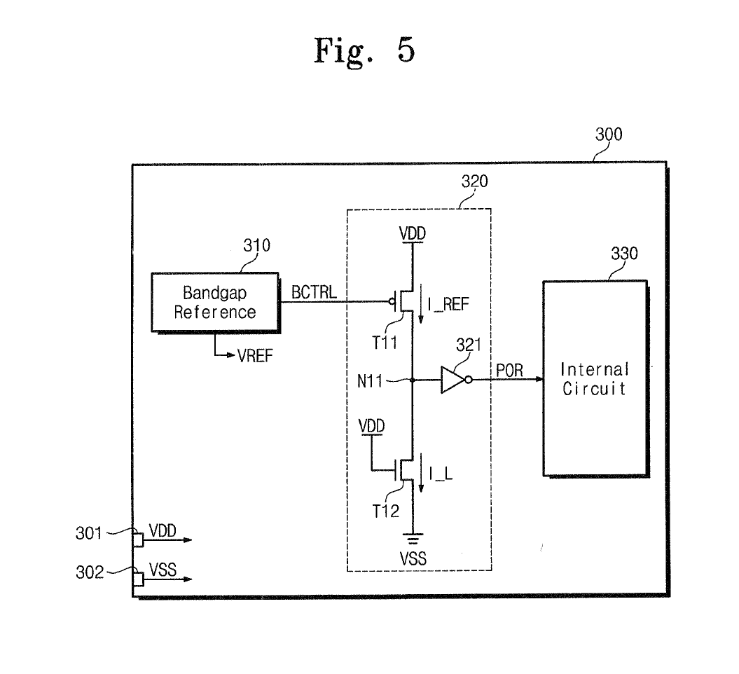

FIG. 5 is a block diagram of an electronic device according to an exemplary embodiment of the inventive concept.

Referring to FIG. 5, an electronic device 300 may include a first terminal 301, a second terminal 302, a bandgap reference 310, a power-on reset circuit 320, and an internal circuit 330.

The electronic device 300 may be one of various devices (e.g., a smart card, a memory card, a microprocessor chip, a system on a chip, an IC card, etc.), which operates using an externally provided power supply voltage and includes the power-on reset circuit 320. A smart card may be a pocket-sized card with embedded integrated circuits. The smart card may include memory (e.g., volatile or non-volatile) and other microprocessor components. The smart card can provide services such as identification, authentication, data storage, and application processing.

The first terminal 301 is supplied with a power supply voltage VDD from an external device, and the second terminal 302 is supplied with a ground voltage VSS from the external device.

The bandgap reference 310 may be configured to generate a bandgap reference voltage VREF having a stable voltage level and a bias control signal BCTRL dependent upon a peripheral temperature. The bandgap reference 310 may be configured the same as the bandgap reference 112 in FIG. 4, for example.

The power-on reset circuit 320 receives the bias control signal BCTRL from the bandgap reference 310, and activates a power-on reset signal POR to a high level when the power supply voltage VDD increases to a predetermined level.

The power-on reset circuit 320 may include a first transistor T11, a second transistor T12 and an inverter 321. The first transistor T11 is connected between the power supply voltage VDD and a first node N11, and has a gate connected to receive the bias control signal BCTRL from the bandgap reference 310. The second transistor T12 is connected between the first node N11 and a ground voltage VSS, and has a gate connected with the power supply voltage. The inverter 321 inverts a signal of the first node N11 to output it as a power-on reset signal POR.

The internal circuit 330 operates in response to activation (e.g., high level) of the power-on reset signal POR provided from the power-on reset circuit 320. The internal circuit 330 is supplied with the bandgap reference voltage VREF from the bandgap reference 310.

The amount of a current I_L flowing through the second transistor T12 may vary according to a variation of a peripheral temperature. The bandgap reference 310 generates the bias control signal BCTRL depending upon the peripheral temperature as described in FIG. 4.

The bias control signal BCTRL from the bandgap reference 310 may be used to vary a reference current I_REF, flowing through the first transistor T11, in proportion to the peripheral temperature. For example, when the peripheral temperature increases, the bandgap reference 310 outputs the bias control signal BCTRL so that the reference current I_REF flowing through the first transistor T11 increases. If the peripheral temperature decreases, the bandgap reference 310 outputs the bias control signal BCTRL so that the reference current I_REF flowing through the first transistor T11 decreases. Accordingly, the power-on reset circuit 320 may activate the power-on reset signal POR to a high level when the power supply voltage VDD reaches a predetermined level.

At least one embodiment of the inventive concept enables the power-on reset circuit 320 of a device to operate stably. For example, the device can be made more resistant to temperature changes by addition of the bandgap reference 310 with minimum circuit change and cost increase.

The above-disclosed subject matter is to be considered illustrative, and not restrictive, and is intended to cover all such modifications, enhancements, and other embodiments, which fall within the spirit and scope of the inventive concept.

What is claimed is:

1. A power-on reset circuit comprising:
a current source circuit supplying a current varied according to a temperature to a first node;
a first transistor connected between the first node and a ground voltage and having a gate connected with a power supply voltage; and
an output circuit connected with the first node and outputting a power-on reset signal in response to a signal of the first node.

2. The power-on reset circuit of claim 1, wherein the current source circuit comprises:
a second transistor connected between the power supply voltage and the first node and having a gate connected to receive a bias control signal; and
a reference voltage generator outputting the bias control signal, and wherein the reference voltage generator comprises:
a third transistor connected between the power supply voltage and a reference voltage node and having a gate connected to receive the bias control signal; and
a bias control circuit outputting the bias control signal to enable output of a stable reference voltage to the reference voltage node.

3. The power-on reset circuit of claim 2, wherein the bias control circuit comprises:
a first resistor connected between the reference voltage node and a second node;
a first diode connected between the second node and a ground voltage;
a second resistor connected between the reference voltage node and a third node;
a third resistor connected between the third node and a fourth node;
a second diode connected between the fourth node and the ground voltage; and
an operational amplifier having a first input terminal connected with the second node, a second input terminal connected with the third node, and an output terminal outputting the bias control signal.

4. The power-on reset circuit of claim 3, wherein the first diode includes a plurality of diodes connected in a parallel with one another between the second node and the ground voltage.

5. The power-on reset circuit of claim 1, wherein the output circuit comprises an inverter which inverts a signal applied to the first node and outputs the inverted signal as the power-on reset signal.

6. The power-on reset circuit of claim 1, wherein the current source circuit is configured to increase the current supplied to the first node when the temperature increases.

7. The power-on reset circuit of claim 1, wherein the current source circuit is configured to decrease the current supplied to the first node when the temperature decreases.

8. An electronic device comprising:
a bandgap reference outputting a bias control signal depending on a peripheral temperature;
a power-on reset circuit outputting a power-on reset signal when a power supply voltage increases to a predetermined level; and
an internal circuit operating in response to the power-on reset signal,
wherein the power-on reset circuit comprises:
a first transistor connected between the power supply voltage and a first node and having a gate connected to receive the bias control signal;
a second transistor connected between the first node and a ground voltage and having a gate connected with the power supply voltage; and
an inverter outputting the power-on reset signal in response to a signal of the first node.

9. The electronic device of claim 8, wherein the bandgap reference comprises:
a third transistor connected between the power supply voltage and a reference voltage node and having a gate connected to receive the bias control signal;
a first resistor connected between the reference voltage node and a second node;
a first diode connected between the second node and the ground voltage;
a second resistor connected between the reference voltage node and a third node;
a third resistor connected between the third node and a fourth node;
a second diode connected between the fourth node and the ground voltage; and
an operational amplifier having a first input terminal connected with the second node, a second input terminal connected with the third node, and an output terminal outputting the bias control signal.

10. The electronic device of claim 9, further comprising:
a first terminal receiving the power supply voltage; and
a second terminal receiving the ground voltage.

11. The electronic device of claim 8, wherein the bandgap reference varies a voltage of the bias control signal in proportion to the peripheral temperature.

12. The electronic device of claim 8, wherein the electronic device is a smart card.

13. The electronic device of claim 9, wherein the first diode includes a plurality of diodes that are connected in parallel with one another between the second node and the ground voltage.

14. A power-on reset circuit comprising:
a first transistor connected between a first node and a ground voltage and having a gate connected with a power supply voltage;
an output circuit connected to the first node and outputting a power-on reset signal based on a signal applied to the first node; and
a current source circuit configured to supply a first current to the first node when a threshold voltage of the first transistor is a value, supply a second current to the first node when the threshold voltage is lower than the value, and supply a third current to the first node when the threshold voltage is higher than the value,
wherein the first current is lower than the second current and higher than the third current.

15. The power-on reset circuit of claim 14, wherein the current source circuit supplies the first current when a current temperature is within a normal temperature operating range for the first transistor, supplies the second current when the current temperature is above the range, and supplies the third current when the current temperature is below the range.

16. The power-on reset circuit of claim 14, wherein the output circuit is an inverter.

17. The power-on reset circuit of claim 14, wherein the current source circuit comprises a second transistor that is connected between the power supply voltage and the first node, wherein the current source circuit varies a control signal in proportion to a peripheral temperature and applies the control signal to a gate of the second transistor.

18. The power-on reset circuit of claim 14, wherein the current source circuit further comprises:
a third transistor connected between the power supply voltage and a reference voltage node and having a gate connected to receive the control signal; and
an operational amplifier having a first input terminal connected to a second node, a second input terminal connected to a third node, and output terminal outputting the control signal.

19. The power-on reset circuit of claim 18, wherein the current source circuit further comprises:
a first resistor connected between the reference voltage node and the second node; and
a second resistor connected between the reference voltage node and the third node.

20. The power-on reset circuit of claim 18, wherein the current source circuit further comprises:
a first diode connected between the second node and a ground voltage; and
a second diode connected between the third node and the ground voltage.
